(19) United States
(12) Patent Application Publication
(10) Pub. No.: US 2009/0001419 A1
(43) Pub. Date: Jan. 1, 2009

(54) Non-Volatile Memory Devices and Methods of Fabricating the Same

(75) Inventors: Jeong-hee Han, Gyeonggi-do (KR); Ji-young Kim, Gyeonggi-do (KR); Kang Lung Wang, Santa Monica, CA (US); Chung-woo Kim, Gyeonggi-do (KR); Soo-doo Chae, Gyeonggi-do (KR); Chan-jin Park, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/056,383

(22) Filed: Mar. 27, 2008

(30) Foreign Application Priority Data
Mar. 27, 2007 (KR) 10-2007-0030047

(51) Int. Cl. H01L 29/778; H01L 29/792; H01L 21/336

(52) U.S. Cl. 257/190; 257/324; 438/287; 257/E29.246; 257/E29.309; 257/E21.403

(57) ABSTRACT

Provided are non-volatile memory devices that may realize high integration and have high reliability. A plurality of first semiconductor layers are stacked on a substrate. A plurality of second semiconductor layers are interposed between the plurality of first semiconductor layers, respectively, and are recessed from one end of each of the plurality of first semiconductor layers to define a plurality of first trenches between the plurality of first semiconductor layers. A plurality of first storage nodes are provided on surfaces of the second semiconductor layers inside the plurality of first trenches. Devices may include a plurality of first control gate electrodes that are formed on the plurality of first storage nodes to fill the plurality of first trenches.

### CROSS-REFERENCE TO RELATED PATENT APPLICATIONS

This application claims the benefit of Korean Patent Application No. 10-2007-0030047, filed on Mar. 27, 2007, in the Korean Intellectual Property Office, the disclosure of which is incorporated herein in its entirety by reference.

### BACKGROUND

The present invention relates to semiconductor devices, and more particularly, to non-volatile memory devices that store and read data and methods of fabricating the same.

Recently, large-capacity portable electronic devices, for example, digital cameras, MP3 players or the like have garnered substantial interest. These electronic devices may benefit from having a smaller size and a larger capacity. Miniaturization and high-capacity of electronic devices may benefit from high integration and/or high capacity of non-volatile memory devices used in such electronic devices.

However, degrees of integration of non-volatile memory devices by forming highly integrated patterns may be limited by process technology. In addition, as integration of a conventional planar non-volatile memory device increases, the performance of conventional planar non-volatile memory devices due to a short channel effect may be degraded. Furthermore, cross coupling and signal interference may occur between adjacent memory cells. Thus, high integration of planar non-volatile memory devices may reduce the reliability of such devices.

### SUMMARY OF THE INVENTION

The present invention provides non-volatile memory devices that may realize high integration and have high reliability. Some embodiments of such memory devices may include multiple first semiconductor layers stacked on a substrate and multiple second semiconductor layers interposed between the first semiconductor layers, respectively, and recessed from one end of each of the first semiconductor layers to define multiple first trenches between the first semiconductor layers. Embodiments may include multiple first storage nodes on surfaces of the second semiconductor layers inside the first trenches and multiple first control gate electrodes formed on the first storage nodes to fill the first trenches.

In some embodiments, the first semiconductor layers have a first conductivity type and the second semiconductor layers have a second conductivity type that is substantially opposite the first conductivity type. In some embodiments, the first semiconductor layers include source and/or drain regions and the second semiconductor layers include a channel region. In some embodiments, the substrate includes a first material, the first semiconductor layers include the first material, and the second semiconductor layers are interposed between the substrate and the first semiconductor layers.

In some embodiments, the first control gate electrodes extend to outsides of the first semiconductor layers and are bent to be disposed on the substrate in an upward direction. Some embodiments provide that the first control gate electrodes are formed to have a substantially “L” shape. Some embodiments include an interlevel dielectric layer interposed between portions of the first control gate electrodes outside the first semiconductor layers. In some embodiments, the first storage nodes further extend onto surfaces of the second semiconductor layers inside the plurality of first trenches.

In some embodiments, the first storage nodes include multiple first tunneling insulating layers, multiple first charge storage layers covering respective ones of the first tunneling insulating layers, and multiple first blocking insulating layers covering respective ones of the first charge storage layers. Some embodiments include a plurality of bit line electrodes that are configured to be electrically connected to uppermost portions of respective ones of the first semiconductor layers.

In some embodiments, the first semiconductor layers and the second semiconductor layers include different ones selected from an Si (silicon) epitaxial layer and an SiGe (silicon germanium) epitaxial layer. In some embodiments, the second semiconductor layers are further recessed from another end of each the first semiconductor layers to define multiple second trenches between the first semiconductor layers, wherein the second trenches are positioned at opposite sides of the first trenches and between the first semiconductor layers. In some embodiments, widths of the second semiconductor layers are smaller than widths of the first semiconductor layers. Some embodiments include multiple second storage nodes on surfaces of the second semiconductor layers inside the second trenches and multiple second control gate electrodes formed on the second storage nodes to fill the second trenches.

Some embodiments of the present invention include methods of fabricating a non-volatile memory device. Some embodiments of such methods may include alternately stacking multiple first semiconductor layers and multiple second semiconductor layers on a substrate and recessing the second semiconductor layers from one end of each of the first semiconductor layers to define multiple first trenches between the plurality of first semiconductor layers. Some embodiments include forming multiple first storage nodes on surfaces of the second semiconductor layers inside the first trenches and forming multiple first control gate electrodes on the first storage nodes to fill the first trenches.

In some embodiments, the first semiconductor layers have a first conductivity type and the second semiconductor layers have a second conductivity type that is substantially opposite the first conductivity type. In some embodiments, the first semiconductor layers and the second semiconductor layers include different ones selected from an Si (silicon) epitaxial layer and an SiGe (silicon germanium) epitaxial layer.

Some embodiments include, after stacking the first semiconductor layers and the second semiconductor layers, further recessing the second semiconductor layers from other ends of the first semiconductor layers to define multiple second trenches between the first semiconductor layers that are positioned at substantially opposite sides than the first trenches. In some embodiments, recessing the second semiconductor layers to define the first trenches and further recessing the second semiconductor layers to define the second trenches are simultaneously performed. In some embodiments, recessing the second semiconductor layers to define the first trenches and further recessing the second semiconductor layers to define the second trenches use isotropic etching. Some embodiments include forming multiple second storage nodes on surfaces of the second semiconductor layers inside the second trenches and forming multiple second control gate electrodes on the second storage nodes to fill the second trenches.

In some embodiments, stacking of the first semiconductor layers and the second semiconductor layers includes extending the first semiconductor layers and the second semiconductor layers onto the substrate in an upward direction along a column insulating layer on the substrate. Some embodiments include, after forming of the first control gate electrodes, forming multiple third trenches between the first control gate electrodes to classify the first semiconductor layers and the second semiconductor layers into multiple stack structures. Such embodiments may include filling a device isolation layer in the third trenches between the stack structures.

After forming the first control gate electrodes, some embodiments include selectively etching upward-extended portions of the first semiconductor layers and the second semiconductor layers to form multiple fourth trenches and filling the fourth trenches with an interlevel dielectric layer. In some embodiments, forming the first storage nodes includes forming multiple first tunneling insulating layers on surfaces of the first semiconductor layers inside the first trenches, forming multiple first charge storage layers to cover respective ones of the second tunneling insulating layers and forming multiple first blocking insulating layers to cover respective ones of the first charge storage layers. Some embodiments include forming multiple bit line electrodes that are configured to be electrically connected to uppermost portions of respective ones of the first semiconductor layers.

### BRIEF DESCRIPTION OF THE DRAWINGS

FIG. 1 is a perspective view of a non-volatile memory device according to some embodiments of the present invention.

FIG. 2 is a cross-sectional view taken along line II-II′ of the non-volatile memory device illustrated in FIG. 1.

FIGS. 3 through 11 are cross-sectional views illustrating methods of fabricating a non-volatile memory device according to some embodiments of the present invention.

### DETAILED DESCRIPTION OF THE INVENTION

The present invention will now be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

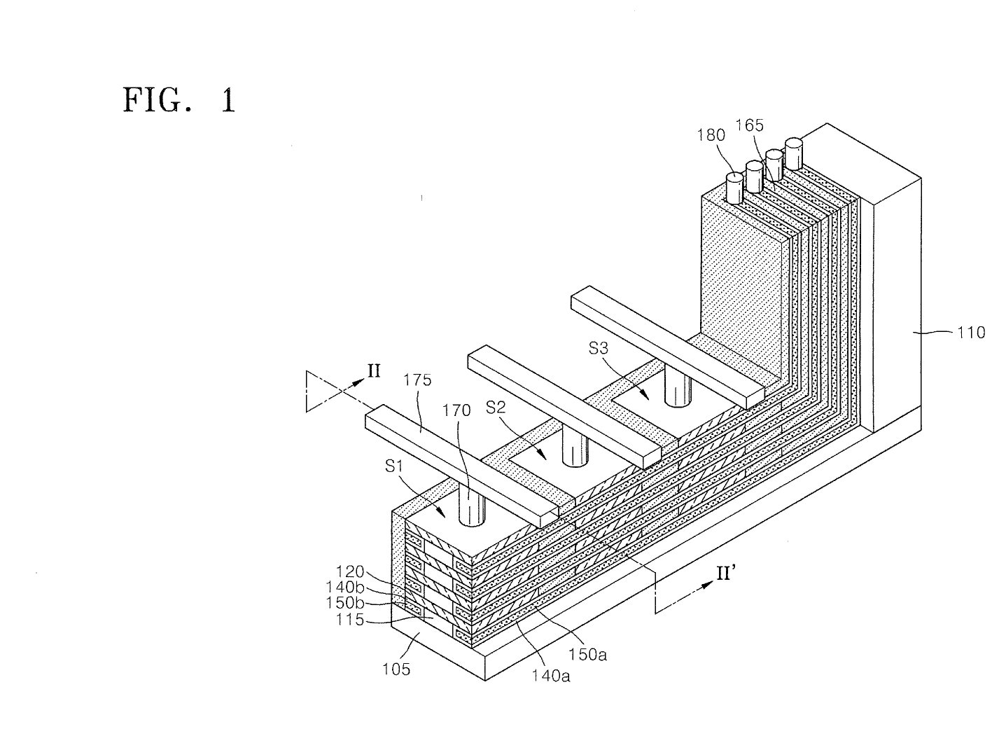

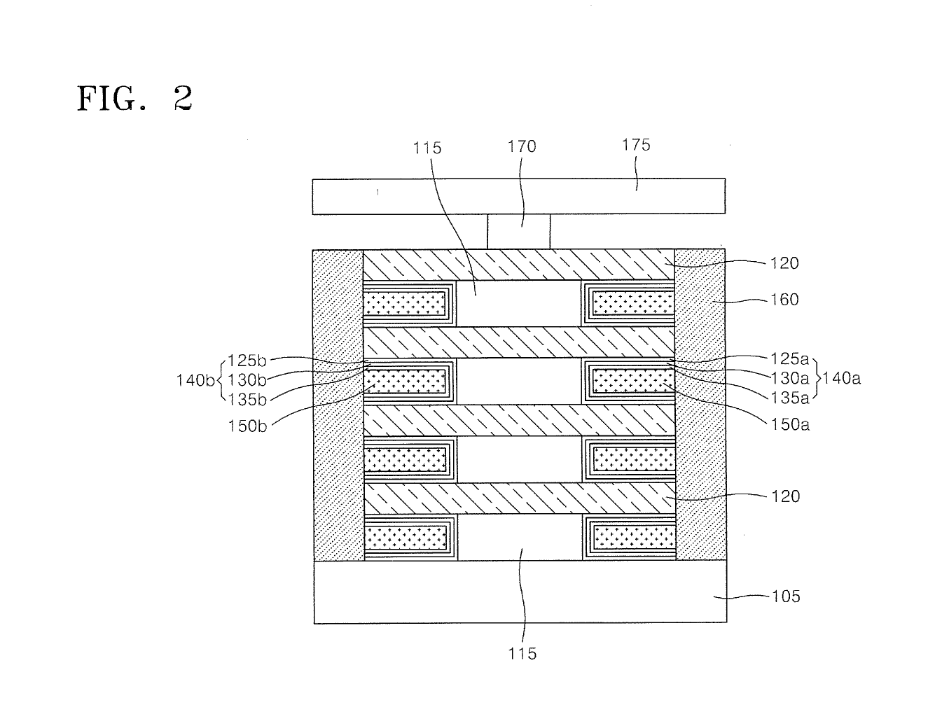

FIG. 1 is a perspective view of a non-volatile memory device according to some embodiments of the present invention. FIG. 2 is a cross-sectional view taken along line II-II′ of the non-volatile memory device illustrated in FIG. 1. Referring to FIGS. 1 and 2, stack structures S1, S2, and S3 including multiple first semiconductor layers 120 and second semiconductor layers 115 may be provided on a substrate 105. The first semiconductor layers 120 and the second semiconductor layers 115 may be alternately stacked on the substrate 105. A device isolation layer 160 may be interposed between the stack structures S1, S2, and S3.

In some embodiments, the first semiconductor layers 120 may be used as source and drain regions and the second semiconductor layers 115 may be used as a channel region. Uppermost portions of the first semiconductor layers 120 may be electrically connected to bit line electrodes 175 using first contact plugs 170. The first semiconductor layers 120 may have a first conductivity type and the second semiconductor layers 115 may have a second conductivity type that is opposite the first conductivity type. The first conductivity type and the second conductivity type may include different types selected from, for example, an n type and/or a p type.

The first semiconductor layers 120 and the second semiconductor layers 115 may be formed in an epitaxial layer using different materials to have etching selectivity. For example, the first semiconductor layers 120 and the second semiconductor layers 115 may include different layers selected from a silicon (Si) epitaxial layer and silicon germanium (SiGe) epitaxial layer.

The substrate 105 may be formed of the same material as a material used in forming the first semiconductor layers 120 and/or the second semiconductor layers 115. For example, when one of the second semiconductor layers 115 is formed directly on the substrate 105, the substrate 105 may have a first conductivity type that is substantially the same as that of the first semiconductor layers 120. Thus, in some embodiments, the substrate 105 may be used as source and/or drain regions. In some embodiments, the substrate 105 may also be formed of an insulating material. In this regard, some embodiments provide that one of the first semiconductor layers 120 may be formed directly on the substrate 105.

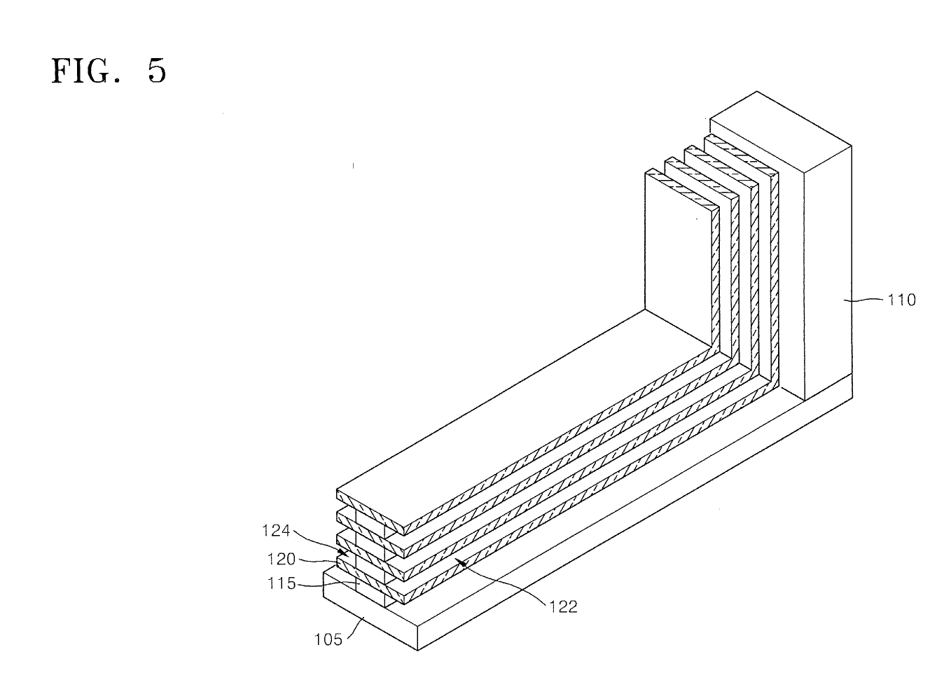

The second semiconductor layers 115 may be recessed to a predetermined depth from both ends of the first semiconductor layers 120. As such, multiple first trenches (122 of FIG. 5) and second trenches (124 of FIG. 5) may be defined between the first semiconductor layers 120 in the spaces where the second semiconductor layers 115 are recessed from the ends of the first semiconductor layers 120. Thus, in some embodiments, the width of the second semiconductor layers 115 may be smaller than the width of the first semiconductor layers 120.

In some embodiments, the second semiconductor layers 115 may be recessed into only one end of the first semiconductor layers 120 so that one of the first trenches 122 and the second trenches 124 may be omitted. In some embodiments, the other ends of the first semiconductor layers 120 and the second semiconductor layers 115 may not be aligned with one another. In this regard, the width of the second semiconductor layers 115 and the width of the first semiconductor layers 120 may be arbitrarily selected.

Multiple first storage nodes 140a and second storage nodes 140b may be formed on at least the surfaces of the second semiconductor layers 115 inside the first trenches 122. In some embodiments, the first storage nodes 140a and the second storage nodes 140b may be further extended onto the surfaces of the first semiconductor layers 120 inside the first trenches 122.

In FIG. 1, the first storage nodes 140a and the second storage nodes 140b are illustrated as one layer. In some embodiments, as illustrated in FIG. 2, the first storage nodes 140a may include multiple tunneling insulating layers 125, charge storage layers 130a, and/or blocking insulating layers 135a. Some embodiments provide that the second storage nodes 140b may include multiple tunneling insulating layers 125b, charge storage layers 130b, and/or blocking insulating layers 135b.

In some embodiments, the tunneling insulating layers 125a and 125b may be formed on the surfaces of the first semiconductor layers 120 and may extend onto the surfaces of the second semiconductor layers 115. Some embodiments provide that the charge storage layers 130a and 130b may cover the tunneling insulating layers 125a and 125b. In some embodiments, the blocking insulating layers 135a and 135b may cover the charge storage layers 130a and 130b.

Some embodiments provide that the tunneling insulating layers 125a and 125b and/or the blocking insulating layers 135a and 135b include an oxide layer, a nitride layer and/or a high dielectric layer. In some embodiments, the high dielectric layer may denote an insulating layer having a higher dielectric constant than a dielectric constant of the oxide layer and/or the nitride layer. Some embodiments provide that the charge storage layers 130a and 130b may include polysilicon, a nitride layer, dots structure and/or nanocrystallines structure. The dots structure and the nanocrystallines structure may include metal and/or semiconductor micro-structures.

In some embodiments, the first control gate electrodes 150a may be formed on the first storage nodes 140a to fill the trenches 122. The second control gate electrodes 150b may be formed on the second storage nodes 140b to fill the second trenches 124. In some embodiments, the first control gate electrodes 150a and/or the second control gate electrodes 150b may include a conductive layer such as polysilicon, metal and/or metal silicide.

Some embodiments provide that the first control gate electrodes 150a and the second control gate electrodes 150b may extend to the outsides of the first semiconductor layers 120 and may be bent. In this regard, the second control gate electrodes 150b may be disposed on the substrate 105 in an upward direction. In some embodiments, the first control gate electrodes 150a and the second control gate electrodes 150b may be formed to have a substantially “L” shape. In some embodiments, the first control gate electrodes 150a and the second control gate electrodes 150b may not be bent vertically and may be ascended at a predetermined angle. As illustrated in FIG. 1, the upward arrangement of the second control gate electrodes 150b may refer to the shape of the first control gate electrodes 150a according to some embodiments.

In some embodiments, the first control gate electrodes 150a and the second control gate electrodes 150b may be separated from each other. Accordingly, lengths of the first control gate electrodes 150a and the second control gate electrodes 150b may be reduced when viewed toward an upward direction from the substrate 105. By virtue of the substantially “L” shape, the circuit distribution of the first control gate electrodes 150a and the second control gate electrodes 150b may be easily performed. For example, the first control gate electrodes 150a and the second control gate electrodes 150b may be electrically connected to word line electrodes (not shown) using contact plugs 180.

The non-volatile memory device according to some embodiments may have an NAND array structure. The stack structures S1, S2, and S3 of the first semiconductor layers 120 and the second semiconductor layers may constitute a pair of NAND strings, respectively. In some embodiments, multiple memory transistors may be connected to one NAND string in series vertically on the substrate 105. In FIG. 1, the number of memory transistors is illustrative.

In the stack structures S1, S2, and S3, NAND strings may be disposed vertically on the substrate 105. In non-volatile memory devices having the stack structures S1, S2, and S3, the area of one NAND string occupied in the substrate 105 may be greatly reduced compared to a general planar structure. Accordingly, integration of non-volatile memory devices may be increased.

In some embodiments, in the stack structures S1, S2, and S3, the heights of the second semiconductor layers 115 may be adjusted so that channel lengths of memory transistors can be easily adjusted. In this manner, the channel lengths of the memory transistors may be increased without increasing the area of the memory transistors occupied on the substrate 105. Accordingly, the short channel effect of a memory transistor may be suppressed. Furthermore, some embodiments provide that the heights of the first semiconductor layers 120 may be adjusted so the vertical separation distance of the memory transistor can be adjusted. As such, cross coupling or interference that may occur between adjacent memory transistors may be reduced. In this regard, the reliability of the non-volatile memory device may be improved.

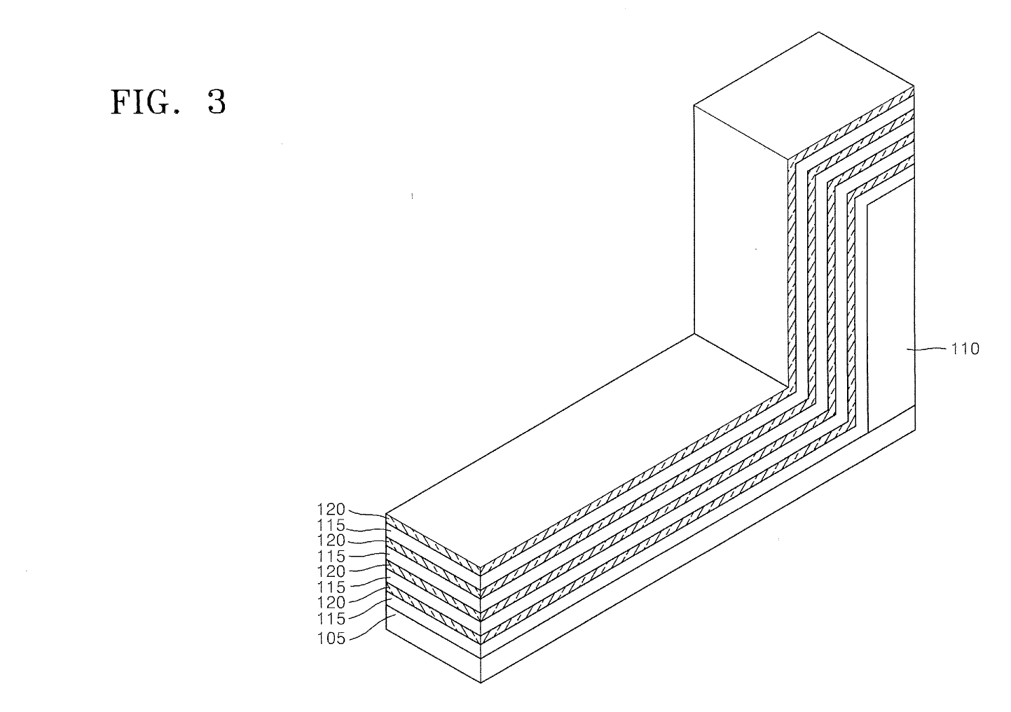

FIGS. 3 through 11 are cross-sectional views illustrating methods of fabricating a non-volatile memory device according to some embodiments of the present invention. Referring to FIG. 3, a column insulating layer 110 may be formed on part of a substrate 105. Subsequently, first semiconductor layers 120 and second semiconductor layers 115 may be alternately stacked on the substrate 105 having the column insulating layer 110. As such, part of the first semiconductor layers 120 and/or the second semiconductor layers 115 may be disposed on the substrate 105 in an upper direction along the column insulating layer 110.

In some embodiments, the column insulating layer 110 may be formed by forming a nitride layer and then patterning the nitride layer. The first semiconductor layers 120 and the second semiconductor layers 115 may be formed of epitaxial layers. In some embodiments, the first semiconductor layers 120 may be formed of silicon (Si) epitaxial layers and the second semiconductor layers 115 may be formed of silicon germanium (SiGe) epitaxial layers. In some embodiments, the first semiconductor layers 120 may be formed of SiGe epitaxil layers and the second semiconductor layers 115 may be formed of silicon epitaxial layers. Some embodiments provide that each of the first semiconductor layers 120 and the second semiconductor layers 115 may have etching selectivity with respect to each other.

In some embodiments, the first semiconductor layers 120 may have a first conductivity type and the second semiconductor layers 115 may have a second conductivity type that is different from the first conductivity type. Some embodiments provide that the first semiconductor layers 120 and the second semiconductor layers 115 may be doped with impurities of a first conductivity type and a second conductivity type, respectively, simultaneously when and/or after they are deposited. In some embodiments, before the first semiconductor layers 120 and the second semiconductor layers 115 are formed, the substrate 105 may be doped with the first conductivity type impurities.

In some embodiments, the first semiconductor layers 120 and the second semiconductor layers 115 may be formed of the same material. For example, the first semiconductor layers 120 and the second semiconductor layers 115 may also be formed by properly etching a bulk semiconductor wafer.

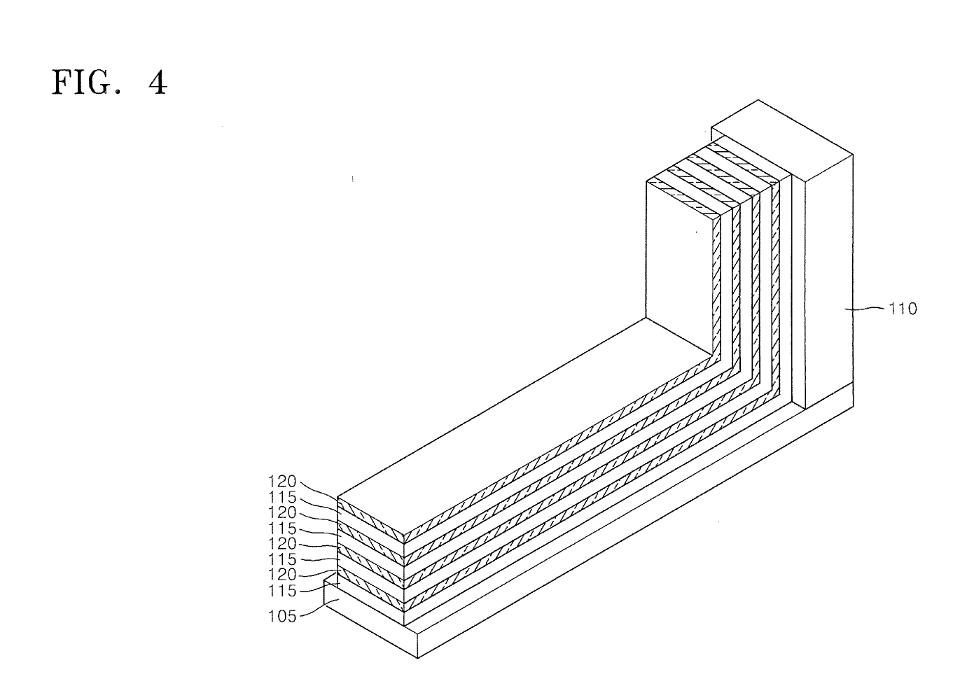

Referring to FIG. 4, the first semiconductor layers 120 and the second semiconductor layers 115 may be patterned so that part of an upper surface of the substrate 105 can be exposed. In some embodiments, after patterning, the widths of the first semiconductor layers 120 and the second semiconductor layers 115 may be between 50 nm and 150 nm. Subsequently, the first semiconductor layers 120 and the second semiconductor layers 115 on the column insulating layer 110 may be removed. Some embodiments provide that the first semiconductor layers 120 and the second semiconductor layers 115 may be planarized to expose the column insulating layer 110 using chemical mechanical polishing (CMP).

Referring to FIG. 5, the second semiconductor layers 115 may be recessed from both ends of the first semiconductor layers 120 so that a plurality of first trenches 122 and a plurality of second trenches 124 may be formed. In some embodiments, the first trenches 122 and the second trenches 124 may be disposed at opposite sides based on the second semiconductor layers 115. Accordingly, the first trenches 122 and the second trenches 124 may be defined between the first semiconductor layers 120. In some embodiments, the first semiconductor layers 120 may be used as source and/or drain regions and the second semiconductor layers 115 may be used as a channel region.

In some embodiments, the second semiconductor layers 115 may be isotropically etched laterally to a predetermined depth so that the first trenches 122 and the second trenches 124 may be simultaneously formed. Some embodiments provide that the isotropic etching may be wet etching and/or chemical dry etching. In some embodiments, the first trenches 122 and the second trenches 124 may be symmetrically formed. Some embodiments provide that the lateral depths of the first trenches 122 and the second trenches 124 may be between 20 nm and 40 nm. In some embodiments, the remaining second semiconductor layers 115 may be used as a channel region.

In some embodiments, one of the first trenches 122 and the second trenches 124 may be omitted. In this regard, one end of each of the first semiconductor layers 120 and/or the second semiconductor layers 115 may be protected using a mask layer (not shown) and the other end of each of the second semiconductor layers 115 may be laterally etched to a predetermined depth to form the first trenches 122 or the second trenches 124.

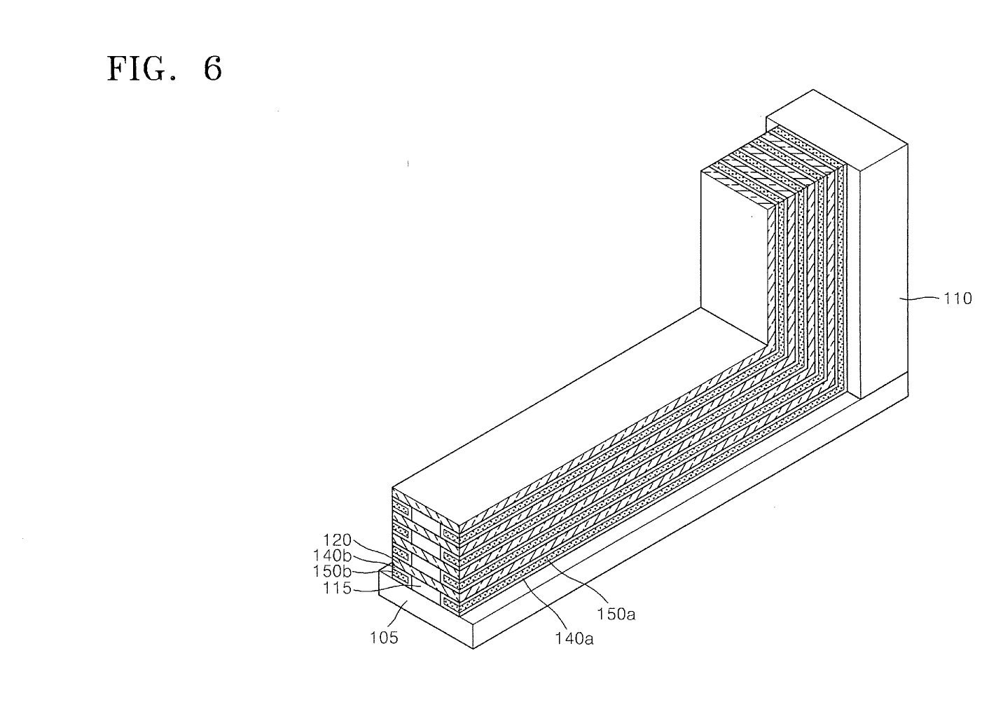

Referring to FIG. 6, multiple first storage nodes 140a may be formed on the surfaces of the second semiconductor layers 115 inside the first trenches 122. For example, as illustrated in FIG. 2, the first storage nodes 140a may include multiple first tunneling insulating layers 125a, multiple first charge storage layers 130a, and/or multiple first blocking insulating layers 135a.

Simultaneously with forming of the first storage nodes 140a, multiple second storage nodes 140b may be formed on the surfaces of the first semiconductor layers 120 inside the second trenches 124. For example, as illustrated in FIG. 2, the second storage nodes 140b may include multiple second tunneling insulating layers 125b, multiple second charge storage layers 130a, and/or a multiple second blocking insulating layers 135a.

In some embodiments, the first storage nodes 140a may extend onto the surfaces of the first semiconductor layers 120 inside the first trenches 122. Some embodiments provide that the second storage nodes 140b may extend onto the surfaces of the first semiconductor layers 120 inside the second trenches 124.

When the first storage nodes 140a and the second storage nodes 140b are formed of the same material simultaneously, the number of processes may be reduced and an economic improvement may be realized. In some embodiments, the first storage nodes 140a and the second storage nodes 140b may be formed of different materials in an arbitrary sequence.

Some embodiments provide that multiple first control gate electrodes 150a may be formed on the first storage nodes 140a to fill the first trenches 122 and multiple second control gate electrodes 150b may be formed on the second storage nodes 140b to fill the second trenches 124. The first control gate electrodes 150a and the second control gate electrodes 150b may extend to the outside of ones of the first semiconductor layers 120 and/or may extend onto the substrate 105 in an upward direction along the column insulating layer 110. In some embodiments, the first control gate electrodes 150a and the second control gate electrodes 150b may be formed to have a substantially “L” shape.

In some embodiments, a conductive layer such as polysilicon, metal and/or metal silicide may be formed to fill the first trenches 122 and/or the second trenches 124. Some embodiments provide that the conductive layer may be patterned and/or planarized so that the first control gate electrodes 150a and the second control gate electrodes 150b can be simultaneously formed. When the first control gate electrodes 150a and the second control gate electrodes 150b are formed of the same material simultaneously, the number of processes may be reduced and an economic benefit may be realized. In some embodiments, the first control gate electrodes 150a and the second control gate electrodes 150b may be formed of different conductive layers in an arbitrary sequence.

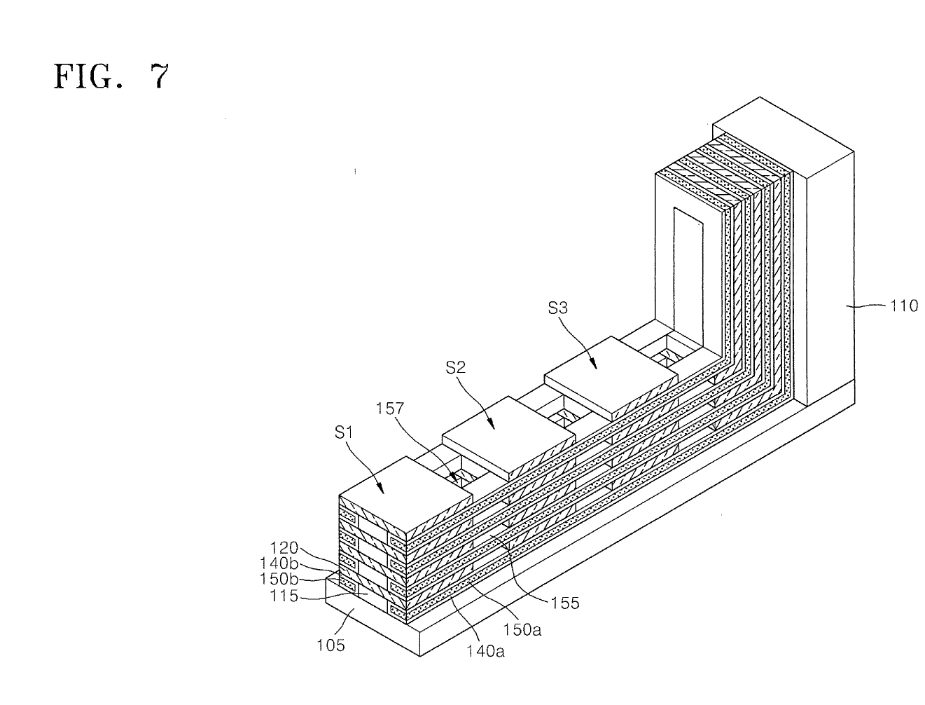

Referring to FIG. 7, the first semiconductor layers 120 and the second semiconductor layers 115 may be divided into multiple stack structures S1, S2, and S3. In some embodiments, the stack structures S1, S2, and S3 may be covered with an etching mask (not shown). In this manner, predetermined portions of the first semiconductor layers 120 and/or the second semiconductor layers 115 exposed from the first and second control gate electrodes 150a and 150b may be selectively first-etched, thereby forming grooves 157. Subsequently, portions of the first semiconductor layers 120 between the first control gate electrodes 150a and the second control gate electrodes 150b may be selectively second-etched to be connected to the grooves 157.

In some embodiments, first etching may be anisotropic etching and second etching may be isotropic etching. Anisotropic etching may include dry etching and isotropic etching may include wet etching or chemical dry etching.

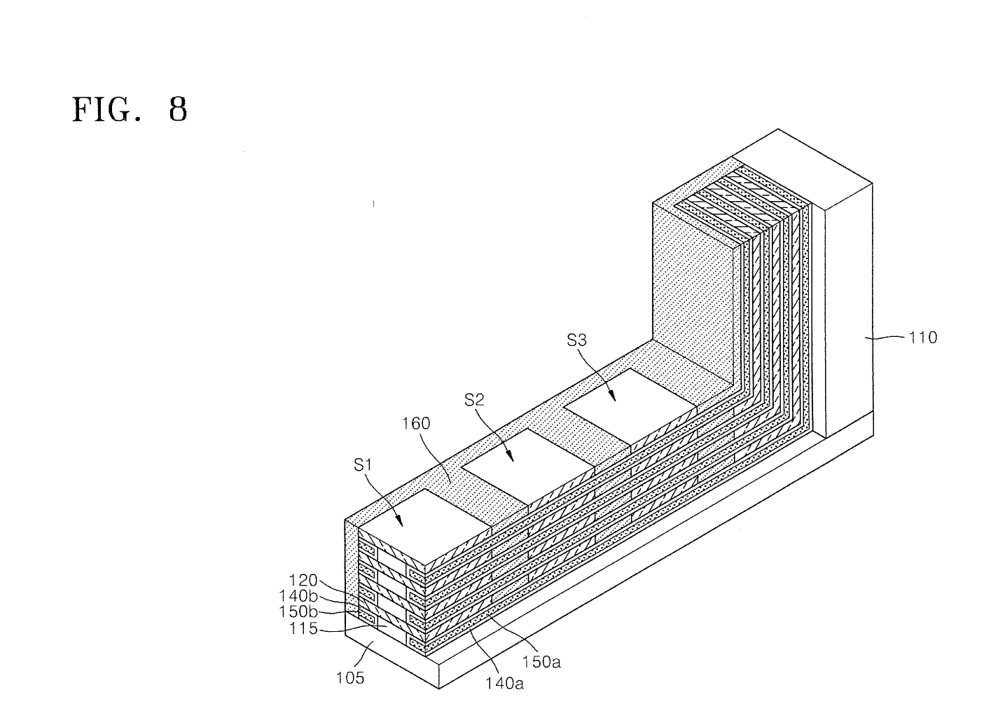

Referring to FIG. 8, a device isolation layer 160 may be filled between the stack structures S1, S2, and S3. In some embodiments, the device isolation layer 160 may be formed by burying an insulating layer on the substrate 105 to bury the grooves 157 and third trenches 155 and then by planarizing and/or patterning the insulating layer. Some embodiments provide that the device isolation layer 160 may include an oxide layer, a nitride layer and/or a high dielectric layer.

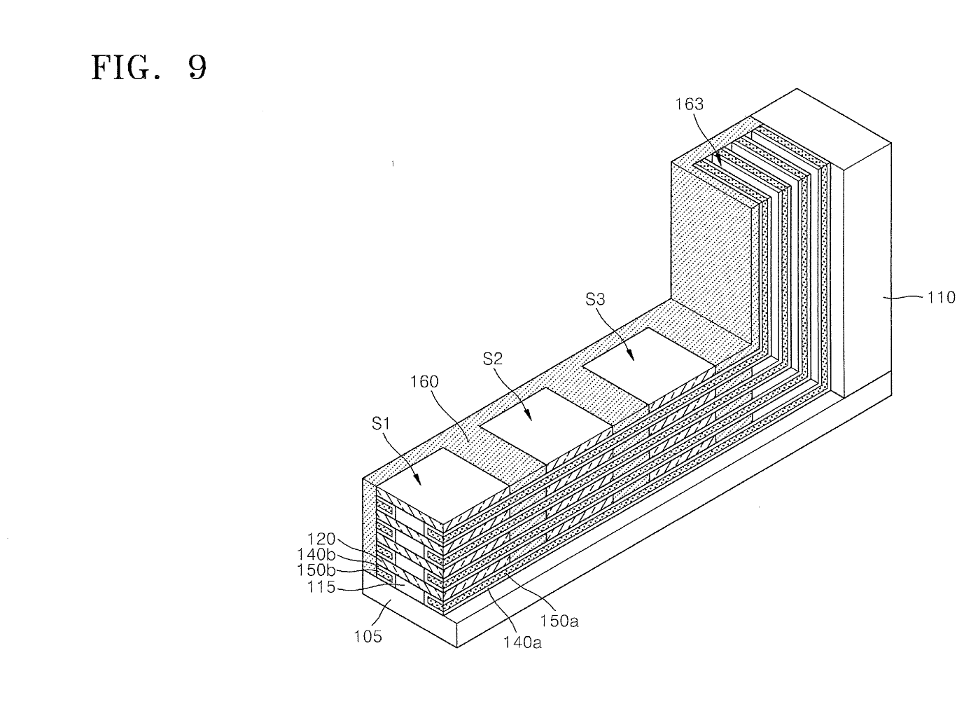

Referring to FIG. 9, the upward arrangement of the first semiconductor layers 120 and the second semiconductor layers 115 may be selectively removed. As such, in some embodiments, multiple fourth trenches 163 may be formed between the first control gate electrodes 150a. Some embodiments provide that the upward arrangement of the first semiconductor layers 120 and the second semiconductor layers 115 may be removed using dry etching. In some embodiments, wet etching may be performed subsequent to dry etching.

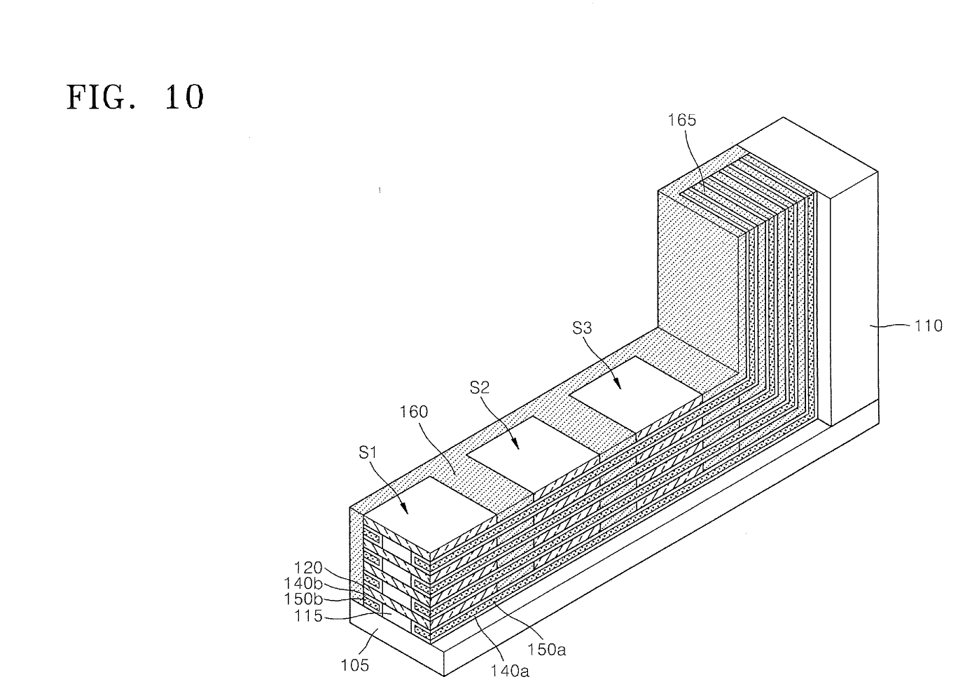

Referring to FIG. 10, interlevel dielectric (ILD) layers 165 may be formed to bury the fourth trenches 163. In some embodiments, the ILD layers 165 may be formed by forming and planarizing an oxide layer, a nitride layer and/or a high dielectric layer. In this regard, the first control gate electrodes 150a that constitute an interconnection line may be insulated from one another reliably.

In some embodiments, forming the grooves 157 and the third trenches 155 of FIG. 7 and forming the fourth trenches 163 of FIG. 9 may be performed simultaneously. Some embodiments provide that forming of the device isolation layer 160 of FIG. 8 and forming of the ILD layers 165 of FIG. 10 may be performed simultaneously.

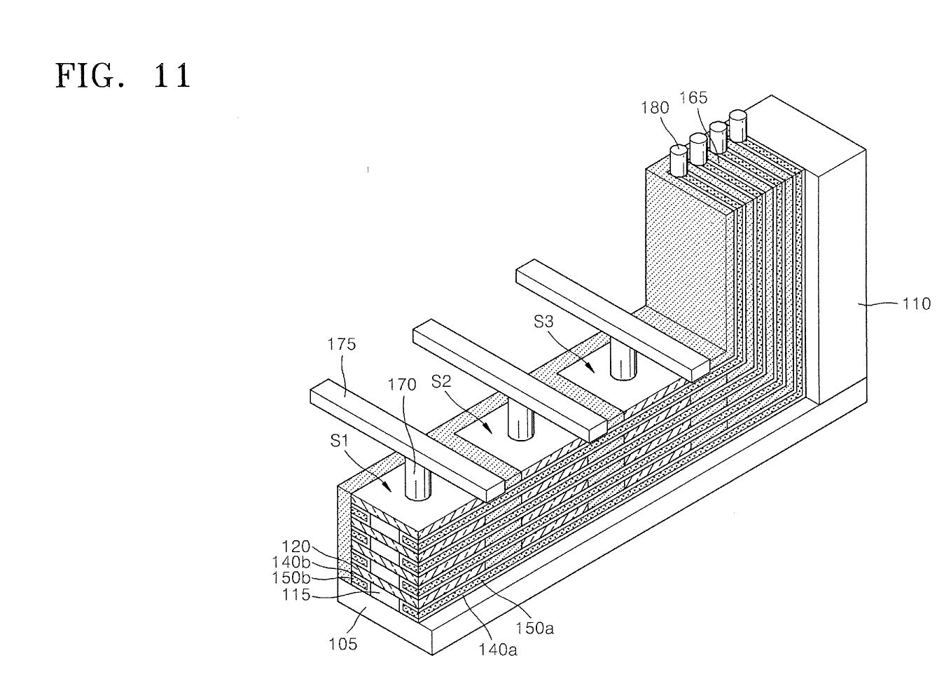

Referring to FIG. 11, bit line electrodes 175 may be formed to be electrically connected to uppermost portions of the first semiconductor layers 120 having stack structures. In some embodiments, first contact plugs 170 may be formed on the uppermost portions of the first semiconductor layers 120. Some embodiments provide that the bit line electrodes 175 may be formed on the first contact plugs 170. In some embodiments, second contact plugs 180 may be formed on the first control gate electrodes 150a. Word line electrodes (not shown) may be formed on the second contact plugs 180.

Forming of the second control gate electrodes 150b to have a substantially “L” shape is omitted in FIGS. 3 through 11. Some embodiments provide that by forming of the first control gate electrodes 150a to have a substantially “L” shape, the “L” shape structure of the second control gate electrodes 150b may be easily formed.

As described above, non-volatile memory devices according to some embodiments of the present invention may include stack structures and may provide higher integration compared to general planar structures. For example, in some embodiments, a NAND string may be vertically disposed on a substrate.

In addition, non-volatile memory devices may provide high reliability. For example, in some embodiments, the channel lengths of the memory transistors may be adjusted and a short channel effect may be reduced and/or suppressed. In addition, a vertical separation distance between memory transistors may be adjusted and cross coupling and/or interference that may occur between adjacent memory transistors may be reduced.

Although the present invention has been described in terms of specific embodiments, the present invention is not intended to be limited by the embodiments described herein. Thus, the scope may be determined by the following claims.

1. A non-volatile memory device, comprising:
a plurality of first semiconductor layers stacked on a substrate;
a plurality of second semiconductor layers interposed between the plurality of first semiconductor layers, respectively, and recessed from one end of each of the plurality of first semiconductor layers to define a plurality of first trenches between the plurality of first semiconductor layers;
a plurality of first storage nodes on surfaces of the second semiconductor layers inside the plurality of first trenches; and
a plurality of first control gate electrodes formed on the plurality of first storage nodes to fill the plurality of first trenches.

2. The non-volatile memory device of claim 1, wherein the plurality of first semiconductor layers have a first conductivity type and the plurality of second semiconductor layers have a second conductivity type that is substantially opposite the first conductivity type.

3. The non-volatile memory device of claim 2, wherein the plurality of first semiconductor layers comprise source and/or drain regions and the plurality of second semiconductor layers comprise a channel region.

4. The non-volatile memory device of claim 2, wherein the substrate comprises a first material, the plurality of first semiconductor layers comprise the first material, and the plurality of second semiconductor layers are interposed between the substrate and the first semiconductor layers.

5. The non-volatile memory device of claim 1, wherein the plurality of first control gate electrodes extend to outsides of the plurality of first semiconductor layers and are bent to be disposed on the substrate in a n upward direction.

6. The non-volatile memory device of claim 5, wherein the plurality of first control gate electrodes are formed to have a substantially “L” shape.

7. The non-volatile memory device of claim 5, further comprising an interlevel dielectric layer interposed between portions of the plurality of first control gate electrodes outside the plurality of first semiconductor layers.

8. The non-volatile memory device of claim 1, wherein the plurality of first storage nodes further extend onto surfaces of the plurality of second semiconductor layers inside the plurality of first trenches.

9. The non-volatile memory device of claim 1, wherein the plurality of first storage nodes comprise:
a plurality of first tunneling insulating layers;
a plurality of first charge storage layers covering respective ones of the plurality of first tunneling insulating layers; and
a plurality of first blocking insulating layers covering respective ones of the plurality of first charge storage layers.

10. The non-volatile memory device of claim 1, further comprising a plurality of bit line electrodes that are configured to be electrically connected to uppermost portions of respective ones of the plurality of first semiconductor layers.

11. The non-volatile memory device of claim 1, wherein the plurality of first semiconductor layers and the plurality of second semiconductor layers comprise different ones selected from an Si (silicon) epitaxial layer and an SiGe (silicon germanium) epitaxial layer.

12. The non-volatile memory device of claim 1, wherein the plurality of second semiconductor layers are further recessed from another end of each the plurality of first semiconductor layers to define a plurality of second trenches between the plurality of first semiconductor layers, wherein the plurality of second trenches are positioned at opposite sides of the plurality of first trenches and are between the plurality of first semiconductor layers.

13. The non-volatile memory device of claim 12, wherein widths of the plurality of second semiconductor layers are smaller than widths of the plurality of first semiconductor layers.

14. The non-volatile memory device of claim 2, further comprising:
a plurality of second storage nodes on surfaces of the second semiconductor layers inside the plurality of second trenches; and
a plurality of second control gate electrodes formed on the plurality of second storage nodes to fill the plurality of second trenches.

15. A method of fabricating a non-volatile memory device, the method comprising:
alternately stacking a plurality of first semiconductor layers and a plurality of second semiconductor layers on a substrate;
recessing the plurality of second semiconductor layers from one end of each of the plurality of first semiconductor layers to define a plurality of first trenches between the plurality of first semiconductor layers;
forming a plurality of first storage nodes on surfaces of the second semiconductor layers inside the plurality of first trenches; and
forming a plurality of first control gate electrodes on the plurality of first storage nodes to fill the plurality of first trenches.

16. The method of claim 15, wherein the plurality of first semiconductor layers have a first conductivity type and the plurality of second semiconductor layers have a second conductivity type that is substantially opposite the first conductivity type.

17. The method of claim 15, wherein the plurality of first semiconductor layers and the plurality of second semiconductor layers comprise different ones selected from an Si (silicon) epitaxial layer and an SiGe (silicon germanium) epitaxial layer.

18. The method of claim 15, wherein, after stacking the plurality of first semiconductor layers and the plurality of second semiconductor layers, further comprising further recessing the plurality of second semiconductor layers from other ends of the plurality of first semiconductor layers to define a plurality of second trenches between the plurality of first semiconductor layers that are positioned at substantially opposite sides than the plurality of first trenches.

19. The method of claim 18, wherein recessing the plurality of second semiconductor layers to define the plurality of first trenches and further recessing the plurality of second semiconductor layers to define the plurality of second trenches are simultaneously performed.

20. The method of claim 18, wherein recessing the plurality of second semiconductor layers to define the plurality of first trenches and further recessing the plurality of second semiconductor layers to define the plurality of second trenches use isotropic etching.

21-25. (canceled)
